(19) United States
(12) Patent Application Publication
(10) Pub. No.: US 2025/0253285 A1
(43) Pub. Date: Aug. 7, 2025

(54) SEMICONDUCTOR PACKAGE

(71) Applicant: Samsung Electronics Co., Ltd., Suwon-si (KR)

(72) Inventor: Kwangyong LEE, Suwon-si (KR)

(73) Assignee: Samsung Electronics Co., Ltd., Suwon-si (KR)

(21) Appl. No.: 18/929,827

(22) Filed: Oct. 29, 2024

(30) Foreign Application Priority Data
Feb. 2, 2024 (KR) 10-2024-0016910

(51) Int. Cl. H01L 23/00; H01L 23/31; H01L 25/00; H01L 25/065

(52) U.S. Cl. CPC H01L 24/48; H01L 23/3107; H01L 25/0657; H01L 25/50; H01L 2224/48227; H01L 2224/48476; H01L 2224/48499; H01L 2225/0651; H01L 2225/06562; H01L 2225/06565

(57) ABSTRACT

A semiconductor package may include a semiconductor die stack in a stepped pattern, an encapsulation layer sealing the semiconductor die stack and including a first surface coplanar with a bottommost surface of the semiconductor die stack and a second surface opposite the first surface, the second surface having a groove, a printed circuit board on the second surface of the encapsulation layer and including a conductive pad facing the second surface of the encapsulation layer, a conductive connector filling the groove, and a bonding wire group penetrating the conductive connector in a vertical direction and connecting the semiconductor die stack to the conductive pad of the printed circuit board. A width of the conductive connector in a lateral direction may be greater than or equal to a width of the conductive pad in the lateral direction.

### CROSS-REFERENCE TO RELATED APPLICATION

This application is based on and claims priority under 35 U.S.C. § 119 to Korean Patent Application No. 10-2024-0016910, filed on Feb. 2, 2024, in the Korean Intellectual Property Office, the disclosure of which is incorporated by reference herein in its entirety.

### BACKGROUND

Inventive concepts relate to a semiconductor package, and more particularly, to a semiconductor package including semiconductor die stacks.

With the rapid development of the electronics industry and users' needs, electronic devices have become compact and light. With the compactness and lightness of electronic devices, semiconductor packages used in the electronic devices have also been compact and light and required to have high reliability. Therefore, it may be required to stack semiconductor dies of a semiconductor package and easily connect the semiconductor dies via bonding wires.

### SUMMARY

Inventive concepts provide a semiconductor package including a plurality of semiconductor die stacks and a bonding wire group capable of easily connecting the semiconductor die stacks to a printed circuit board.

According to an embodiment of inventive concepts, a semiconductor package may include a semiconductor die stack in a stepped pattern; an encapsulation layer sealing the semiconductor die stack and including a first surface and a second surface, the first surface being coplanar with a bottommost surface of the semiconductor die stack and the second surface being opposite the first surface, the second surface having a groove; a printed circuit board on the second surface of the encapsulation layer and including a conductive pad facing the second surface of the encapsulation layer; a conductive connector filling the groove; and a bonding wire group penetrating the conductive connector in a vertical direction and connecting the semiconductor die stack to the conductive pad of the printed circuit board. A width of the conductive connector in a lateral direction may be greater than or equal to a width of the conductive pad in the lateral direction.

According to an embodiment of inventive concepts, a semiconductor package may include a lower semiconductor die stack including a plurality of lower semiconductor dies stacked in a stepped pattern in a first horizontal direction; an upper semiconductor die stack on the lower semiconductor die stack, the upper semiconductor die stack including a plurality of upper semiconductor dies stacked on the lower semiconductor die stack in a stepped pattern in a first reverse horizontal direction opposite to the first horizontal direction; an encapsulation layer sealing the upper semiconductor die stack and the lower semiconductor die stack, the encapsulation layer including a first surface and a second surface, the first surface being coplanar with a bottommost surface of the lower semiconductor die stack and the second surface being opposite to the first surface, the second surface having a plurality of grooves; a printed circuit board on the second surface of the encapsulation layer and including a plurality of conductive pads facing the second surface of the encapsulation layer; a first conductive connector, a second conductive connector, and a third conductive connector respectively filling the plurality of grooves; a first bonding wire group penetrating the first conductive connector in a vertical direction and connecting the lower semiconductor die stack to some of the plurality of conductive pads of the printed circuit board; and a second bonding wire group penetrating the second conductive connector and the third conductive connector in the vertical direction and connecting the upper semiconductor die stack to other conductive pads among the conductive pads of the printed circuit board. A width of the first conductive connector, a width of the second conductive connector, and a width the third conductive connector in a lateral direction may be greater than or equal to widths of each of the plurality of conductive pads in the lateral direction.

According to an embodiment of inventive concepts, a semiconductor package may include a lower semiconductor die stack including a plurality of lower semiconductor dies stacked in a stepped pattern in a first horizontal direction, the first horizontal direction being parallel with surfaces of the plurality of lower semiconductor dies and corresponding to a first step direction in which the plurality of lower semiconductor dies are stacked; an upper semiconductor die stack including a plurality of upper semiconductor dies stacked on the lower semiconductor die stack in a stepped pattern in a first reverse horizontal direction, the first reverse horizontal direction being opposite the first horizontal direction and parallel with surfaces of the plurality of upper semiconductor dies and corresponding to a second step direction in which the plurality of upper semiconductor dies are stacked, the second step direction being opposite the first step direction of the plurality of lower semiconductor dies; an encapsulation layer sealing the upper semiconductor die stack and the lower semiconductor die stack, the encapsulation layer including a first surface and a second surface, the first surface being coplanar with a bottommost surface of the lower semiconductor die stack and the second surface being opposite the first surface, the second surface having a plurality of grooves; a printed circuit board including a solder ball attached to a first photosensitive resist layer, an insulating layer, and a second photosensitive resist layer, the first photosensitive resist layer including a plurality of conductive pads facing the second surface of the encapsulation layer, and the first photosensitive resist layer, the insulating layer, and the second photosensitive resist layer being sequentially stacked on the second surface of the encapsulation layer; a first conductive connector, a second conductive connector, and a third conductive connector respectively filling the plurality of grooves; a first bonding wire group penetrating the first conductive connector in a vertical direction and connecting the lower semiconductor die stack to some of the plurality of conductive pads of the printed circuit board; and a second bonding wire group penetrating the second conductive connector and the third conductive connector in the vertical direction and connecting the upper semiconductor die stack to other conductive pads among the conductive pads of the printed circuit board. A width of the first conductive connector, a width of the second conductive connector, and a width of the third conductive connector in a lateral direction may be greater than or equal to widths of each of the plurality of conductive pads in the lateral direction.

### BRIEF DESCRIPTION OF THE DRAWINGS

Embodiments will be more clearly understood from the following detailed description taken in conjunction with the accompanying drawings in which:

FIG. 1 is a cross-sectional view of a semiconductor package according to an embodiment;

FIG. 2 is an enlarged view of a region CX1 in FIG. 1;

FIG. 3 is an enlarged view of a region CX2 in FIG. 1;

FIG. 4 is a plan view illustrating a state, in which a first lower semiconductor die and a second lower semiconductor die in FIG. 1 are stacked;

FIG. 5 is a cross-sectional view of a semiconductor package according to some embodiments;

FIG. 6 is an enlarged view of a region CX3 in FIG. 5;

FIG. 7 is a cross-sectional view of a semiconductor package according to some embodiments;

FIG. 8 is a cross-sectional view of a semiconductor package according to some embodiments;

FIG. 9 is an enlarged view of a region CX4 in FIG. 8;

FIG. 10 is a cross-sectional view of a semiconductor package according to an embodiment;

FIG. 11 is a cross-sectional view of a semiconductor package according to an embodiment;

FIGS. 12 to 19 are cross-sectional views of operations in a method of manufacturing a semiconductor package, according to an embodiment;

FIGS. 20 to 22 are cross-sectional views of operations in a method of manufacturing a semiconductor package, according to some embodiments;

FIG. 23 is a cross-sectional view of a semiconductor package according to an embodiment; and

FIG. 24 is a cross-sectional view of an operation in a method of manufacturing the semiconductor package of FIG. 23.

### DETAILED DESCRIPTION OF THE EMBODIMENTS

Hereinafter, embodiments are described in detail with reference to the accompanying drawings. However, inventive concepts should not be construed as being limited to the embodiments and may be embodied in other various forms. The embodiments are provided to fully convey the scope of inventive concepts to those skilled in the art rather than to allow inventive concepts to be fully completed.

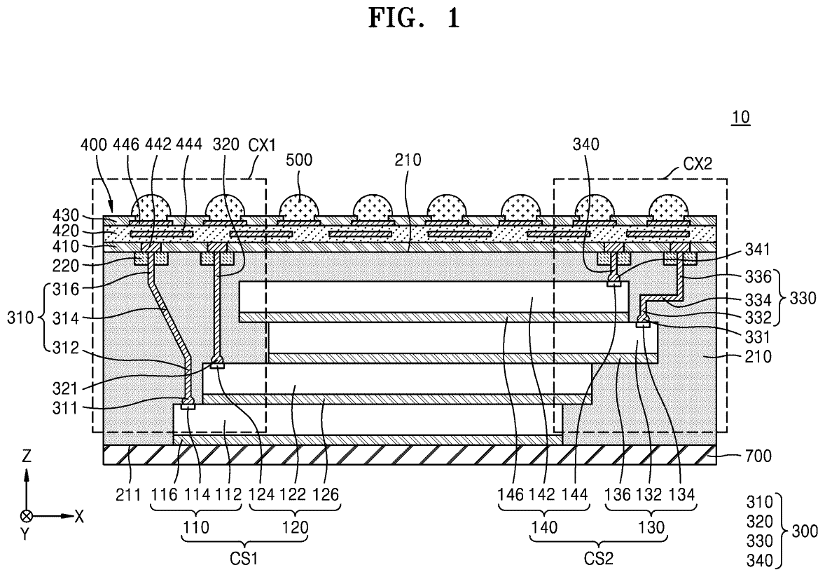

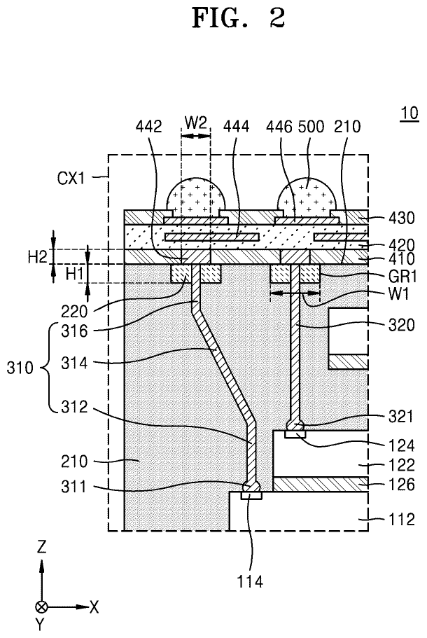

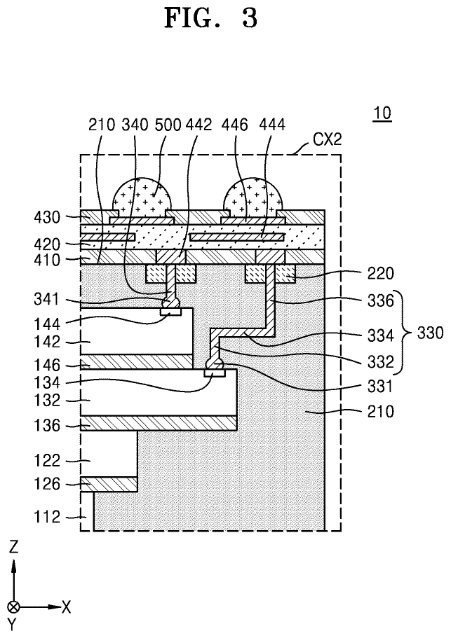

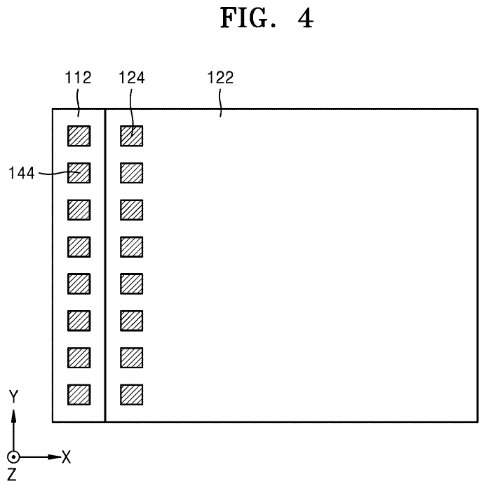

FIG. 1 is a cross-sectional view of a semiconductor package 10 according to an embodiment. FIG. 2 is an enlarged view of a region CX1 in FIG. 1. FIG. 3 is an enlarged view of a region CX2 in FIG. 1. FIG. 4 is a plan view illustrating a state, in which a first lower semiconductor die 110 and a second lower semiconductor die 120 in FIG. 1 are stacked.

The semiconductor package 10 may include a lower semiconductor die stack CS1, an upper semiconductor die stack CS2, an encapsulation layer 210, a conductive connector 220, a bonding wire group 300, a printed circuit board (PCB) 400, and an external connection terminal 500.

The lower semiconductor die stack CS1 may include a plurality of lower semiconductor dies, e.g., two lower semiconductor dies (e.g., 110 and 120), which are stacked in a stepped pattern in a first horizontal direction (an X direction). The first horizontal direction (the X direction) may be a direction that is parallel with the surface of the lower semiconductor dies (110 and 120) and a first step direction in which the lower semiconductor dies (110 and 120) are stacked. The lower semiconductor die stack CS1 may include the first lower semiconductor die 110 at the bottom and the second lower semiconductor die 120 on the first lower semiconductor die 110.

The first lower semiconductor die 110 may include a first lower body 112, a first lower die pad 114, and a first adhesive layer 116. The second lower semiconductor die 120 may include a second lower body 122, a second lower die pad 124, and a second adhesive layer 126.

According to an embodiment, the semiconductor package 10 may further include a backside protective film 700, which is attached to the bottom surface of the first lower body 112 and a first surface 211 of the encapsulation layer 210. The backside protective film 700 may protect the first lower semiconductor die 110 from external physical impact. According to an embodiment, the backside protective film 700 may include a polymeric material. The backside protective film 700 may include a non-adhesive material. In this case, the first adhesive layer 116 may attach the first lower body 112 to the backside protective film 700. In some embodiments, the backside protective film 700 may include an adhesive material. In this case, the first lower body 112 may be directly attached to the backside protective film 700, and thus, the first adhesive layer 116 may not be between the backside protective film 700 and the first lower body 112.

The first lower body 112 and the second lower body 122 may be semiconductor substrates and may include a semiconductor material, e.g., a Group IV semiconductor material, a Group III-V semiconductor material, a Group II-VI semiconductor material, or a combination thereof. For example, the Group IV semiconductor material may include silicon (Si), germanium (Ge), or a combination thereof. For example, the Group III-V semiconductor material may include gallium arsenide (GaAs), indium phosphide (InP), gallium phosphide (GaP), indium arsenide (InAs), indium antimony (InSb), indium gallium arsenide (InGaAs), or a combination thereof. For example, the Group II-VI semiconductor material may include zinc telluride (ZnTe), cadmium sulfide (CdS) or a combination thereof. The first lower body 112 and the second lower body 122 may include a substrate and an integrated circuit on the substrate. The integrated circuit may include a memory circuit, a logic circuit, or any type of integrated circuit including a combination thereof. For example, the memory circuit may include a dynamic random access memory (DRAM) circuit, a static RAM (SRAM) circuit, a flash memory circuit, an electrically erasable and programmable read-only memory (EEPROM) circuit, a phase-change RAM (PRAM) circuit, a magnetic RAM (MRAM) circuit, a resistive RAM (RRAM) circuit, or a combination thereof. For example, the logic circuit may include a central processing unit (CPU) circuit, a graphics processing unit (GPU) circuit, a controller circuit, an application specific integrated circuit (ASIC), an application processor (AP) circuit, or a combination thereof.

Referring to FIG. 4, a plurality of first lower die pads 114 of the first lower semiconductor die 110 may be apart from each other in a second horizontal direction (a Y direction) and a plurality of second lower die pads 124 of the second lower semiconductor die 120 may be apart from each other in the second horizontal direction (the Y direction). The second horizontal direction (the Y direction) may be a direction that is parallel with the surface of the lower semiconductor dies (110 and 120) and perpendicular to the first horizontal direction (the X direction) on the surface of the lower semiconductor dies (110 and 120). The first lower die pad 114 may be a terminal to which a first bonding portion 310 is connected. The second lower die pad 124 may be a terminal to which a second bonding portion 320 is connected.

The first adhesive layer 116 of the first lower semiconductor die 110 may attached to the bottom surface of the first lower body 112. The first adhesive layer 116 may be between the backside protective film 700 and the first lower body 112. The first adhesive layer 116 may include an insulating adhesive material, e.g., a die attach film (DAF). The thickness of the first adhesive layer 116 may be several tens of micrometers.

The second adhesive layer 126 of the second lower semiconductor die 120 may be attached to the bottom surface of the second lower body 122. The second adhesive layer 126 may be between the first lower semiconductor die 110 and the second lower semiconductor die 120. The second adhesive layer 126 may include an insulating adhesive material, e.g., a DAF. The thickness of the second adhesive layer 126 may be several tens of micrometers.

The upper semiconductor die stack CS2 may include a plurality of upper semiconductor dies, e.g., two upper semiconductor dies (e.g., 130 and 140), which are stacked in a stepped pattern in a first reverse horizontal direction (a −X direction) opposite to the first horizontal direction (the X direction).

The first reverse horizontal direction (the −X direction) may be a direction that is parallel with the surface of the upper semiconductor dies (130 and 140) and a second step direction in which the upper semiconductor dies (130 and 140) are stacked in an opposite direction to the first step direction of the lower semiconductor dies (110 and 120). The upper semiconductor die stack CS2 may include a first upper semiconductor die 130 on the second lower semiconductor die 120 and a second upper semiconductor die 140 on the first upper semiconductor die 130.

The first upper semiconductor die 130 may include a first upper body 132, a first upper die pad 134, and a third adhesive layer 136. The second upper semiconductor die 140 may include a second upper body 142, a second upper die pad 144, and a fourth adhesive layer 146.

The first upper body 132 and the second upper body 142 may have the same or substantially the same configuration as the first lower body 112 and the second lower body 122, and thus, detailed descriptions thereof are omitted.

The first upper die pad 134 may be arranged on one side of the top surface of the first upper body 132 and the second upper die pad 144 may be arranged on one side of the top surface of the second upper body 142. The first upper die pad 134 may be a terminal to which a third bonding portion 330 is connected. The second upper die pad 144 may be a terminal to which a fourth bonding portion 340 is connected.

According to an embodiment, the encapsulation layer 210 may be configured to seal the lower semiconductor die stack CS1 and the upper semiconductor die stack CS2. The encapsulation layer 210 may have the first surface 211, which is coplanar with the bottom surface of the first lower semiconductor die 110 at the bottom of the lower semiconductor die stack CS1, and a second surface 212 opposite to the first surface 211. The height of the encapsulation layer 210 in a vertical direction (a Z direction) may be greater than the sum of the height of the lower semiconductor die stack CS1 in the vertical direction (the Z direction) and the height of the upper semiconductor die stack CS2 in the vertical direction (the Z direction). Herein, the vertical direction (the Z direction) may be defined as a direction, in which semiconductor dies (e.g., 110 and 120) of the lower semiconductor die stack CS1 or semiconductor dies (e.g., 130 and 140) of the upper semiconductor die stack CS2 are stacked, and a direction that is perpendicular to the first horizontal direction (the X direction) and the second horizontal direction (the Y direction).

According to an embodiment, the topmost surface of the second upper semiconductor die 140 at the top of the upper semiconductor die stack CS2 may be apart from the second surface 212 of the encapsulation layer 210 in the vertical direction (the Z direction).

For example, the encapsulation layer 210 may include thermosetting resin such as epoxy resin, thermoplastic resin such as polyimide, or resin, such as Ajinomoto build-up film (ABF), flame retardant 4 (FR-4), or bismalcimide triazine (BT), which includes an inorganic filler. The encapsulation layer 210 may include a molding material, such as an epoxy molding compound (EMC), or a photo-imageable material, such as a photo-imagecable encapsulant (PIE).

A plurality of grooves GR1 may be formed in the second surface 212 of the encapsulation layer 210. The conductive connector 220 may be embedded in each of the grooves GR1, which is described in detail below.

The PCB 400 may be arranged on the second surface 212 of the encapsulation layer 210. The PCB 400 may include a first photosensitive resist layer 410, an insulating layer 420, a second photosensitive resist layer 430, a conductive pad 442 in the first photosensitive resist layer 410, a conductive pattern 444 embedded in the insulating layer 420, and an external connection pad 446 embedded in the second photosensitive resist layer 430.

The first photosensitive resist layer 410 may be arranged along the second surface 212 of the encapsulation layer 210. A portion of the bottom surface of the first photosensitive resist layer 410 may be in contact with the conductive connector 220 and the other portion of the bottom surface of the first photosensitive resist layer 410 may be in contact with the second surface 212 of the encapsulation layer 210. The conductive pad 442 may be embedded in the first photosensitive resist layer 410 and exposed by the bottom surface of the first photosensitive resist layer 410.

The insulating layer 420 may be disposed on the top surface of the first photosensitive resist layer 410. The conductive pattern 444 may be embedded in the insulating layer 420. The conductive pattern 444 may include a plurality of horizontal patterns, which extend in the first horizontal direction (the X direction) and/or the second horizontal direction (the Y direction) at different vertical levels, and vertical vias, which connect the horizontal patterns at different levels to each other and extend in the vertical direction (the Z direction). For convenience of illustration, the horizontal patterns at different vertical levels and the vertical vias are not shown in the drawings.

The second photosensitive resist layer 430 may be disposed on the top surface of the insulating layer 420. The external connection pad 446 may be embedded in the second photosensitive resist layer 430 and bonded to the external connection terminal 500. For example, the external connection terminal 500 may include a conductive material including tin (Sn), lead (Pb), silver (Ag), copper (Cu), or a combination thereof. For example, the external connection terminal 500 may be formed using a solder ball. The external connection terminal 500 may connect the semiconductor package 10 to a circuit substrate, another semiconductor package, an interposer, or a combination thereof.

The external connection terminal 500 may be bonded to the external connection pad 446. The external connection pad 446 may be configured to electrically and physically connect the external connection terminal 500 to the conductive pattern 444.

For example, the first photosensitive resist layer 410 and the second photosensitive resist layer 430 may include a photo acid generator (PAG) and a photo base generator (PBG). The PAG that has a high light efficiency may be used to generate an acid even at a low exposure dose. The PBG that has a lower light efficiency than the PAG may be used to generate a base event at a high exposure dose.

For example, the insulating layer 420 may include an inorganic insulating material, an organic insulating material, or a combination thereof. For example, the inorganic insulating material may include silicon oxide, silicon nitride, or a combination thereof. For example, the organic insulating material may include polyimide, epoxy resin, or a combination thereof.

The conductive pattern 444, the conductive pad 442, and the external connection pad 446 may include a conductive material including copper (Cu), gold (Au), silver (Ag), nickel (Ni), tungsten (W), aluminum (Al), or a combination thereof. In some embodiments, the conductive pattern 444, the conductive pad 442, and the external connection pad 446 may further include a barrier material, which limits and/or prevents the conductive material from diffusing out of the conductive pattern 444, the conductive pad 442, and the external connection pad 446. For example, the barrier material may include titanium (Ti), tantalum (Ta), titanium nitride (TiN), tantalum nitride (TaN), or a combination thereof.

The bonding wire group 300 may connect the lower semiconductor dies (110 and 120) and the upper semiconductor dies (130 and 140) to the PCB 400. The bonding wire group 300 may include a lower bonding wire group (310 and 320), which connects the lower semiconductor dies (110 and 120) to the PCB 400, and an upper bonding wire group (330 and 340), which connects the upper semiconductor dies (130 and 140) to the PCB 400.

The bonding wire group 300 may include a bonding wire. The bonding wire may include metal, such as gold, silver, copper, or platinum, or an alloy thereof, which may be welded to a die pad by ultrasonic energy and/or heat. The bonding wire may have a length of several hundreds of micrometers (um).

The lower bonding wire group (310 and 320) may include the first bonding portion 310 and the second bonding portion 320, which connect the PCB 400 to a plurality of lower semiconductor dies selected from the lower semiconductor die stack CS1.

In some embodiments, the lower bonding wire group (310 and 320) may connect the first lower semiconductor die 110 and the second lower semiconductor die 120 to the PCB 400. In some embodiments, the upper bonding wire group (330 and 340) may connect the first upper semiconductor die 130 and the second upper semiconductor die 140 to the PCB 400.

The first bonding portion 310 may include a first upward wire 312 which is connected to the first lower die pad 114 of the first lower semiconductor die 110 and directed to the PCB 400, an inclined wire 314 connected to the first upward wire 312, and a second upward wire 316 which extends toward the PCB 400 and connects the inclined wire 314 to the PCB 400.

An end portion of the first upward wire 312 may include a first bulge 311. In a process of bonding the first upward wire 312 to the first lower die pad 114 of the first lower semiconductor die 110, the first upward wire 312 may be pressed against the first lower die pad 114. At this time, the end portion of the first upward wire 312 may be formed into the first bulge 311 due to physical and thermal pressure. The first bulge 311 may be integrated with the first upward wire 312 and does not form an interface with respect to the first upward wire 312.

It is illustrated that the semiconductor package 10 of FIG. 1 includes the inclined wire 314 that is inclined once from the first upward wire 312. However, when the inclined wire 314 is long, the inclined wire 314 may be inclined multiple times, e.g., two times, from the first upward wire 312, according to an embodiment.

An end of the second bonding portion 320 may be connected to the second lower die pad 124 of the second lower semiconductor die 120 and the other end of the second bonding portion 320 may be connected to the PCB 400. The second bonding portion 320 may extend in a straight line toward the conductive connector 220. Like the end portion of the first upward wire 312, an end portion of the second bonding portion 320 may have a second bulge 321. Similarly, in a process of bonding the second bonding portion 320 to the second lower die pad 124 of the second lower semiconductor die 120, the second bonding portion 320 may be pressed against the second lower die pad 124. At this time, the end portion of the second bonding portion 320 may be formed into the second bulge 321 due to physical and thermal pressure. The second bulge 321 may be integrated with the second bonding portion 320 and does not form an interface with respect to the second bonding portion 320.

The upper bonding wire group (330 and 340) may include the third bonding portion 330 and the fourth bonding portion 340, which connect the PCB 400 to a plurality of upper semiconductor dies selected from the upper semiconductor die stack CS2. In some embodiments, the upper bonding wire group (330 and 340) may connect the first upper semiconductor die 130 and the second upper semiconductor die 140 to the PCB 400.

The third bonding portion 330 may include a third upward wire 332 which is connected to the first upper die pad 134 of the first upper semiconductor die 130 and directed to the PCB 400, a horizontal wire 334 connected to the third upward wire 332, and a fourth upward wire 366 which extends toward the PCB 400 and connects the horizontal wire 334 to the PCB 400. An end portion of the third upward wire 332 may include a third bulge 331. In a process of bonding the third upward wire 332 to the first upper die pad 134 of the first upper semiconductor die 130, the third upward wire 332 may be pressed against the first upper die pad 134. At this time, the end portion of the third upward wire 332 may be formed into the third bulge 331 due to physical and thermal pressure The third bulge 331 may be integrated with the third upward wire 332 and does not form an interface with respect to the third upward wire 332.

An end of the fourth bonding portion 340 may be connected to the second upper die pad 144 of the second upper semiconductor die 140 and the other end of the fourth bonding portion 340 may be connected to the PCB 400. The fourth bonding portion 340 may extend in a straight line toward the conductive connector 220. Like the end portion of the third upward wire 332, an end portion of the fourth bonding portion 340 may have a fourth bulge 341. Similarly, in a process of bonding the fourth bonding portion 340 to the second upper die pad 144 of the second upper semiconductor die 140, the fourth bonding portion 340 may be pressed against the second upper die pad 144. At this time, the end portion of the fourth bonding portion 340 may be formed into the fourth bulge 341 due to physical and thermal pressure. The fourth bulge 341 may be integrated with the fourth bonding portion 340 and does not form an interface with respect to the fourth bonding portion 340.

The first upward wire 312, the inclined wire 314, and the second upward wire 316 of the first bonding portion 310 may include a conductive material including copper (Cu), gold (Au), silver (Ag), nickel (Ni), tungsten (W), aluminum (Al), or a combination thereof. In some embodiments, the first upward wire 312, the inclined wire 314, and the second upward wire 316 may further include a barrier material, which limits and/or prevents the conductive material from diffusing out of the first upward wire 312, the inclined wire 314, and the second upward wire 316. For example, the barrier material may include titanium (Ti), tantalum (Ta), titanium nitride (TiN), tantalum nitride (TaN), or a combination thereof. A material included in each of the second bonding portion 320, the third upward wire 332, the horizontal wire 334, the fourth upward wire 336, and the fourth bonding portion 340 may be the same as the material of the first upward wire 312, and thus, detailed descriptions thereof are omitted.

The encapsulation layer 210 may be configured to mold the lower semiconductor die stack CS1, the upper semiconductor die stack CS2, and the bonding wire group 300.

A groove GR1 may be formed in the second surface 212 of the encapsulation layer 210. The groove GR1 may have a first width W1 in the first horizontal direction (the X direction) and a first height H1 in the vertical direction (the Z direction). The conductive pad 442 may have a second width W2 in the first horizontal direction (the X direction) and a second height H2 in the vertical direction (the Z direction). The groove GR1 may be filled with the conductive connector 220. Accordingly, the conductive connector 220 filling the groove GR1 may also have the first width W1 in the first horizontal direction (the X direction) and the first height H1 in the vertical direction (the Z direction). The top surface of the conductive connector 220 may be coplanar with the second surface 212 of the encapsulation layer 210. The conductive connector 220 may fill the groove GR1 so that there is no space within the groove GR1. The first width W1 may be greater than or equal to the second width W2, according to an embodiment, and the first height H1 may be greater than or equal to the second height H2, according to an embodiment.

The PCB 400 may be arranged on the encapsulation layer 210. Because the pitch of the conductive pad 442 of the PCB 400 is greater than that of a redistribution structure (e.g., a redistribution layer (RDL) structure), there may be difficulty in connecting the conductive pad 442 to the bonding wire group 300. In the semiconductor package 10 of inventive concepts, the conductive connector 220 having a width that is greater than the width of the conductive pad 442 in a lateral direction (the X direction and/or the Y direction) may be arranged on the second surface 212 of the encapsulation layer 210, which faces the conductive pad 442. When the conductive pad 442 is arranged on the second surface 212 of the encapsulation layer 210 and the conductive connector 220 mediates the connection between the conductive pad 442 and the bonding wire group 300, the PCB 400 may be easily connected to the bonding wire group 300. According to an embodiment, the width of the conductive connector 220 in the lateral direction (the X direction and/or the Y direction) may be equal to the width of the conductive pad 442 in the lateral direction (the X direction and/or the Y direction). However, the width of the conductive connector 220 in the lateral direction (the X direction and/or the Y direction) may be less than the width of the conductive pad 442 in the lateral direction (the X direction and/or the Y direction). The conductive pad 442 may overlap the conductive connector 220 in the vertical direction (the Z direction) and may be in contact with the conductive connector 220.

According to an embodiment, the conductive connector 220 may include tin (Sn), indium (In), bismuth (Bi), antimony (Sb), copper (Cu), silver (Ag), zinc (Zn), lead (Pb), and/or an alloy thereof. The melting point of a material included in the conductive connector 220 may be lower than the melting point of a conductive material included in the bonding wire group 300.

The conductive pad 442 of the PCB 400 may be aligned with the conductive connector 220. The bonding wire group 300 may be electrically connected to the PCB 400 through the conductive connector 220. The first width W1 of the conductive connector 220 in the first horizontal direction (the X direction) may be greater than the second width W2 of the conductive pad 442 in the first horizontal direction (the X direction). As the first width W1 of the conductive connector 220 is greater than the second width W2 of the conductive pad 442, the conductive pad 442 may be relatively easily connected to the conductive connector 220. When the first width W1 of the conductive connector 220 is less than the second width W2 of the conductive pad 442, there may be difficulty in aligning the conductive pad 442 with the conductive connector 220.

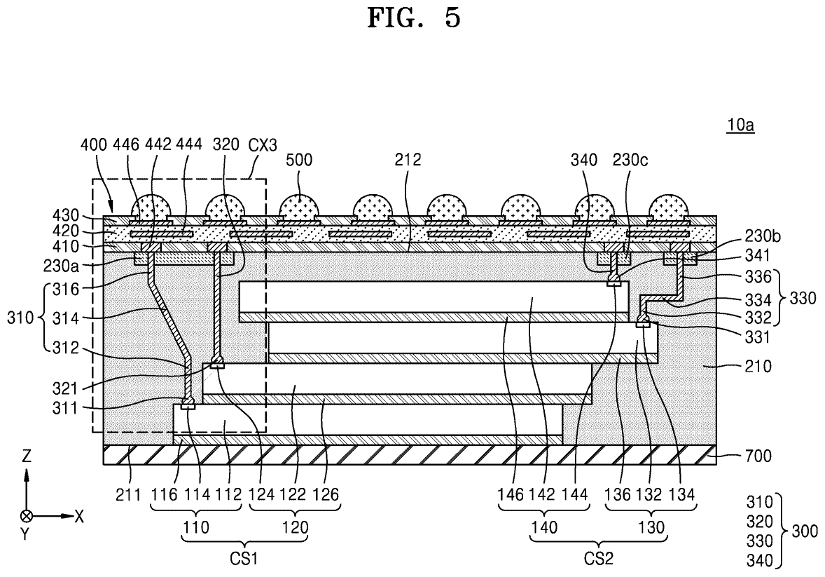

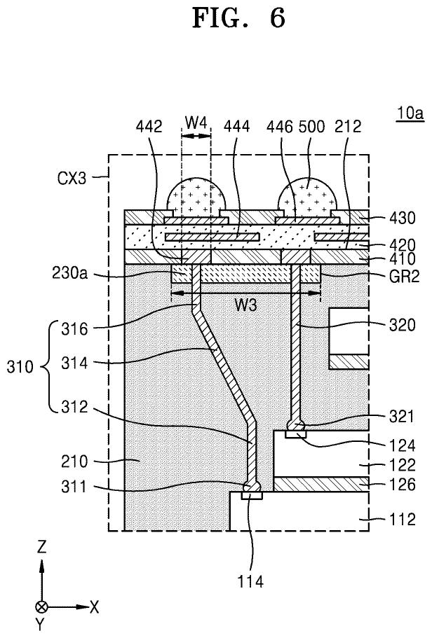

FIG. 5 is a cross-sectional view of a semiconductor package 10a according to some embodiments. FIG. 6 is an enlarged view of a region CX3 in FIG. 5. The semiconductor package 10a of FIGS. 5 and 6 is substantially the same as or similar to the semiconductor package 10 of FIGS. 1 to 4, except for the shape of a first conductive connector 230a. Accordingly, redundant descriptions of the elements described with reference to FIGS. 1 to 4 are brief or omitted.

Referring to FIGS. 5 and 6, a plurality of conductive connectors may include a first conductive connector 230a, a second conductive connector 230b, and a third conductive connector 230c. The width of the first conductive connector 230a in FIGS. 5 and 6 may be greater than the width of the conductive connector 220, which is connected to the first bonding portion 310 or the second bonding portion 320, in the first horizontal direction (the X direction).

The second conductive connector 230b and the third conductive connector 230c in FIG. 5 may be the same or substantially the same as the conductive connector 220 in FIG. 1, and thus, detailed descriptions thereof are omitted.

The first conductive connector 230a in FIG. 5 may be electrically connected to the first bonding portion 310 and the second bonding portion 320. The first bonding portion 310 and the second bonding portion 320 may penetrate the first conductive connector 230a and may be electrically connected to each other via the first conductive connector 230a. For example, the first conductive connector 230a may include a power supply terminal of the semiconductor package 10a. The PCB 400 may be externally supplied with power through the external connection terminal 500, and the power may be supplied to the first conductive connector 230a. Because the first bonding portion 310 is electrically connected to the second bonding portion 320 via the first conductive connector 230a, when power is supplied to the first conductive connector 230a, the power may be transmitted to both the first lower semiconductor die 110 and the second lower semiconductor die 120.

Although not shown in detail in the drawings, in the same principle, power may be supplied to both the first upper semiconductor die 130 and the second upper semiconductor die 140 via other bonding wires respectively connected to first upper semiconductor die 130 and the second upper semiconductor die 140.

However, unlike the first bonding portion 310 and the second bonding portion 320, the third bonding portion 330 and the fourth bonding portion 340 may not be electrically connected to each other. The second conductive connector 230b and the third conductive connector 230c may each function as a signal terminal, and therefore, it may be possible to individually supply and/or discharge energy to and/or from the first upper semiconductor die 130 and the second upper semiconductor die 140.

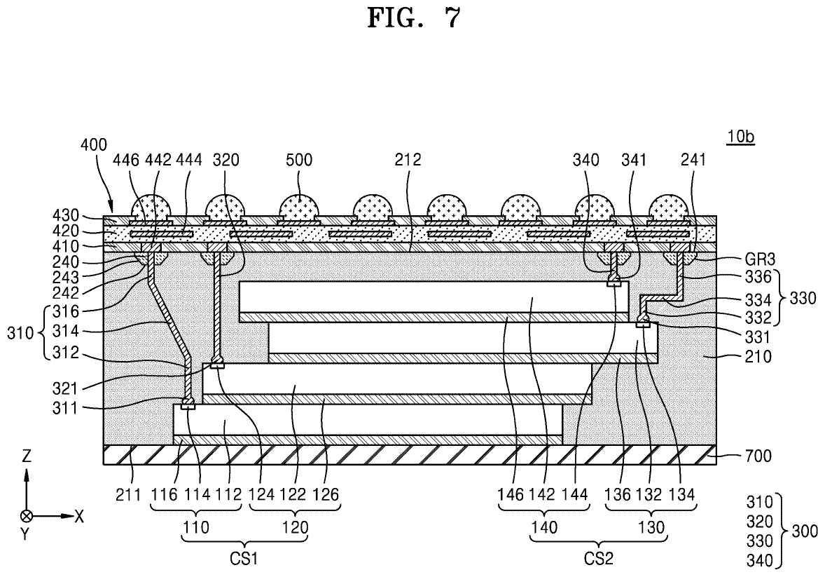

FIG. 7 is a cross-sectional view of a semiconductor package 10b according to some embodiments. The semiconductor package 10b of FIG. 7 is substantially the same as or similar to the semiconductor package 10 of FIGS. 1 to 4, except for the shape of a conductive connector 240. Accordingly, redundant descriptions of the elements described with reference to FIGS. 1 to 4 are brief or omitted.

A groove GR3 may be formed in the second surface 212 of the encapsulation layer 210 of the semiconductor package 10b of FIG. 7. Compared to the groove GR1 in FIGS. 1 and 2, the groove GR3 in FIG. 7 may have a width decreasing in a reverse vertical direction (a-Z direction). The encapsulation layer 210 needs to be etched to form the groove GR3. During the etching process, the groove GR3 may form a tapered shape. Accordingly, the conductive connector 240 filling the groove GR3 may also have a tapered shaped.

The conductive connector 240 may have a top surface 241 in contact with the first photosensitive resist layer 410 of the PCB 400, a bottom surface 242 opposite to the top surface 241, and an inclined surface 243 extending from the top surface 241 to the bottom surface 242. The area of the bottom surface 242 may be less than the area of the top surface 241. As the top surface 241 of the conductive connector 240, which is in contact with the PCB 400, has a larger area than the bottom surface 242 of the conductive connector 240, the conductive connector 240 may have structural stability.

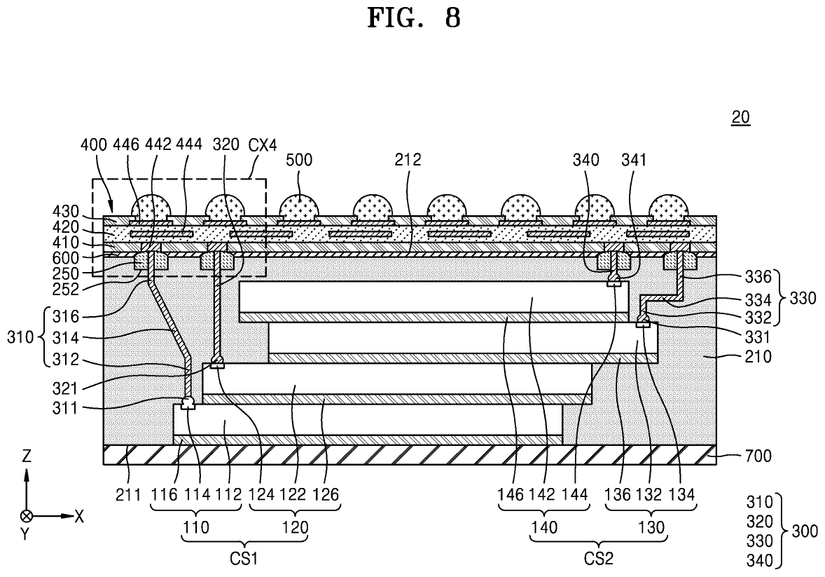

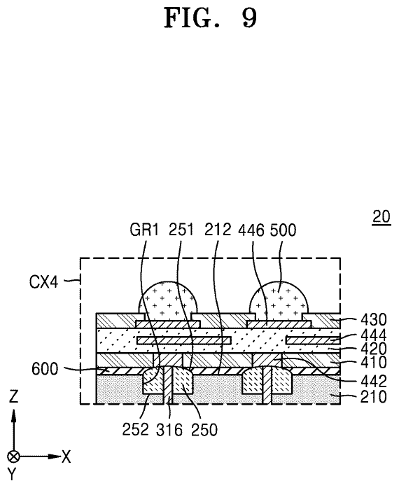

FIG. 8 is a cross-sectional view of a semiconductor package 20 according to some embodiments. FIG. 9 is an enlarged view of a region CX4 in FIG. 9. The semiconductor package 20 of FIG. 8 is substantially the same as or similar to the semiconductor package 10 of FIGS. 1 to 4, except for a non-conductive film 600 and the shape of a conductive connector 250. Accordingly, redundant descriptions of the elements described with reference to FIGS. 1 to 4 are brief or omitted.

The shape of the groove GR1 of the encapsulation layer 210 in FIGS. 8 and 9 may be substantially the same as the shape of the groove GR1 of the encapsulation layer 210 in FIGS. 1 and 2. However, unlike the conductive connector 220 of the semiconductor package 10 of FIGS. 1 to 4, the conductive connector 250 in FIGS. 8 and 9 may have a top surface 251 that is not flat but protrudes toward the PCB 400.

The top surface 251 of the conductive connector 250 may protrude in the vertical direction (the Z direction) such that the vertical level of the topmost end of the conductive connector 250 may be higher than the vertical level of the second surface 212 of the encapsulation layer 210. At this time, the vertical level of the conductive connector 250 may increase toward the center of the conductive connector 250. In a process of forming the conductive connector 250, the groove GR1 may be filled with a conductive material. By applying thermal energy to the conductive material in a reflow process, the conductive material may thermally expand and the central portion of the conductive material may protrude in the vertical direction (the Z direction). Contrarily, the bottom surface 252 of the conductive connector 250 may be flat, like the conductive connector 220 in FIGS. 1 to 4.

The central portion of the top surface 251 of the conductive connector 250 may be in physical contact with the conductive pad 442 of the PCB 400. The remaining portion of the top surface 251 of the conductive connector 250, excluding the portion in contact with the conductive pad 442 of the PCB 400, may be in contact with the non-conductive film 600.

According to an embodiment, the non-conductive film 600 may be between the encapsulation layer 210 and the first photosensitive resist layer 410 of the PCB 400. The non-conductive film 600 may include a material having appropriate adhesion to the first photosensitive resist layer 410 of the PCB 400 such that the PCB 400 is satisfactorily attached to the encapsulation layer 210. However, because the non-conductive film 600 may have low conductivity, in an example embodiment, the non-conductive film 600 may not come into contact with the conductive pad 442 of the PCB 400. The first photosensitive resist layer 410 of the PCB 400 may be in contact with the non-conductive film 600 lengthwise and coplanar with the non-conductive film 600.

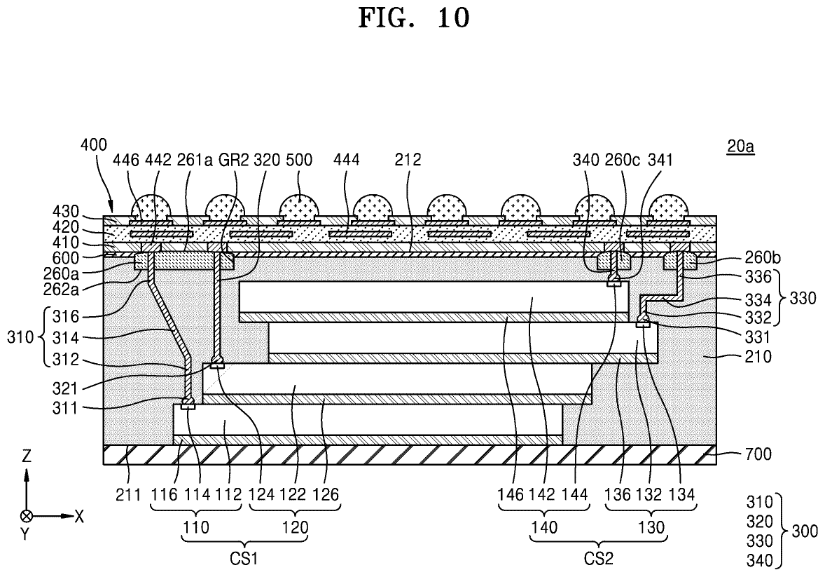

FIG. 10 is a cross-sectional view of a semiconductor package 20a according to some embodiments. The semiconductor package 20a of FIG. 10 is substantially the same as or similar to the semiconductor package 10a of FIG. 5, except for the non-conductive film 600 and the shape of a first conductive connector 260a. Accordingly, redundant descriptions of the elements described with reference to FIGS. 1 to 5 are brief or omitted.

The shape of the groove GR2 of the encapsulation layer 210 in FIG. 10 may be substantially the same as the shape of the groove GR2 of the encapsulation layer 210 in FIG. 5. However, unlike the first conductive connector 220a, the second conductive connector 220b, and the third conductive connector 220c of the semiconductor package 10a of FIG. 5, the first conductive connector 260a, a second conductive connector 260b, and a third conductive connector 260c in FIG. 10 may have a top surface 261a that is not flat but protrudes toward the PCB 400.

The top surface 261a of the first conductive connector 260a may protrude in the vertical direction (the Z direction) such that the vertical level of the topmost end of the first conductive connector 260a may be higher than the vertical level of the second surface 212 of the encapsulation layer 210. The detailed description thereof has been given above with reference to FIG. 9 and is thus omitted below.

The central portion of the top surface 261a of the first conductive connector 260a may be in physical contact with the conductive pad 442 of the PCB 400. The remaining portion of the top surface 261a of the first conductive connector 260a, excluding the portion in contact with the conductive pad 442 of the PCB 400, may be in contact with the non-conductive film 600.

According to an embodiment, the non-conductive film 600 may be between the encapsulation layer 210 and the first photosensitive resist layer 410 of the PCB 400. The detailed description thereof has been given above with reference to FIG. 9 and is thus omitted below.

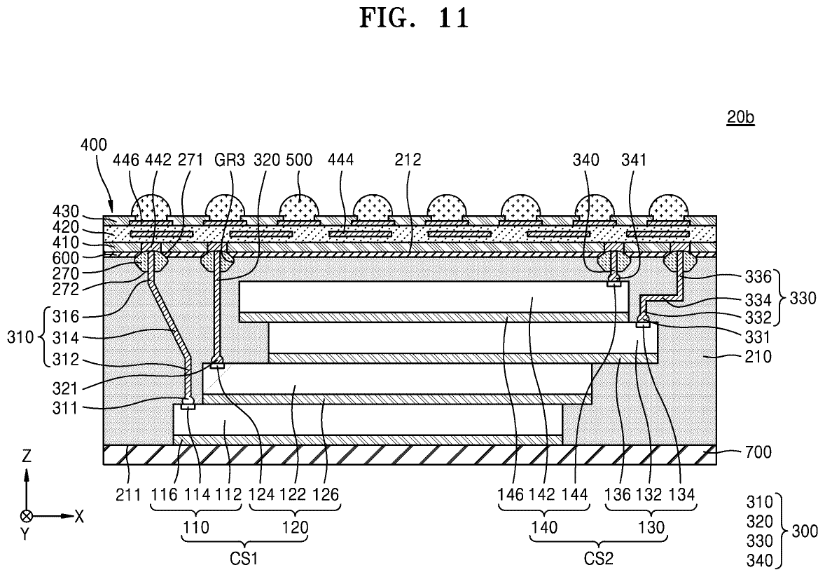

FIG. 11 is a cross-sectional view of a semiconductor package 20b according to some embodiments.

The shape of the groove GR3 of the encapsulation layer 210 in FIG. 11 may be substantially the same as the shape of the groove GR3 of the encapsulation layer 210 in FIG. 7. However, unlike the conductive connector 240 of the semiconductor package 10b of FIG. 7, a conductive connector 270 in FIG. 11 may have a top surface 271 that is not flat but protrudes toward the PCB 400.

A top surface 271 of the conductive connector 270 may protrude in the vertical direction (the Z direction) such that the vertical level of the topmost end of the conductive connector 270 may be higher than the vertical level of the second surface 212 of the encapsulation layer 210. The detailed description thereof has been given above with reference to FIG. 9 and is thus omitted below.

The central portion of the top surface 271 of the conductive connector 270 may be in physical contact with the conductive pad 442 of the PCB 400. The remaining portion of the top surface 271 of the conductive connector 270, excluding the portion in contact with the conductive pad 442 of the PCB 400, may be in contact with the non-conductive film 600.

According to an embodiment, the non-conductive film 600 may be between the encapsulation layer 210 and the first photosensitive resist layer 410 of the PCB 400. The detailed description thereof has been given above with reference to FIG. 9 and is thus omitted below.

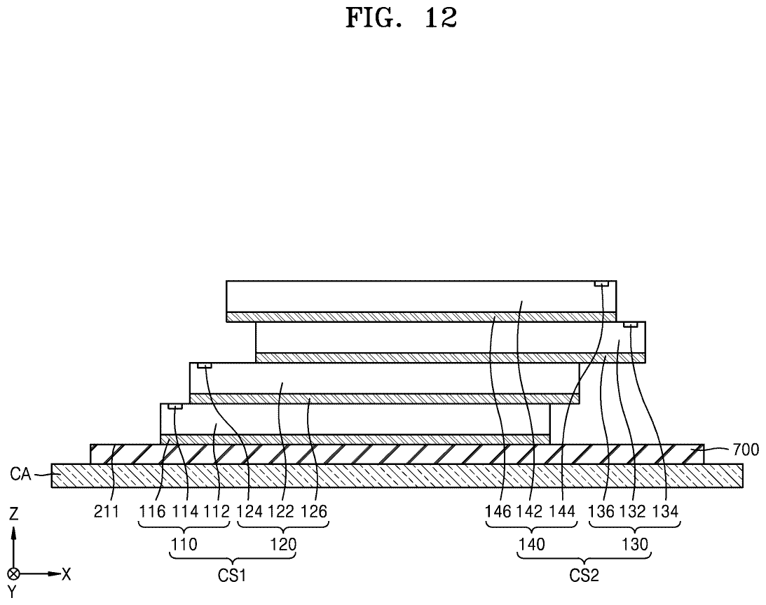

FIGS. 12 to 19 are cross-sectional views of operations in a method of manufacturing the semiconductor package 10, according to an embodiment. The semiconductor package 10 corresponds to the semiconductor package 10 described above with reference to FIGS. 1 to 4.

Redundant descriptions given above with reference to FIGS. 1 to 4 are brief or omitted. Referring to FIG. 12, the lower semiconductor die stack CS1 and the upper semiconductor die stack CS2 may be formed on a carrier substrate CA. The carrier substrate CA may include a glass carrier substrate, a silicon carrier substrate, or a ceramic carrier substrate. Alternatively, the carrier substrate CA may include a wafer.

The lower semiconductor die stack CS1 may include the first lower semiconductor die 110 in contact with the carrier substrate CA and the second lower semiconductor die 120 on the first lower semiconductor die 110. The upper semiconductor die stack CS2 may include the first upper semiconductor die 130 in contact with the second lower semiconductor die 120 and the second upper semiconductor die 140 on the first upper semiconductor die 130.

The lower semiconductor die stack CS1 may be formed by stacking a plurality of lower semiconductor dies, e.g., two lower semiconductor dies (110 and 120), on the carrier substrate CA in a stepped pattern in the first horizontal direction (the X direction). The first horizontal direction (the X direction) may be a direction that is parallel with the surface of the lower semiconductor dies (110 and 120) and a first step direction in which the lower semiconductor dies (110 and 120) are stacked. The upper semiconductor die stack CS2 may be formed by stacking a plurality of upper semiconductor dies, e.g., two upper semiconductor dies (130 and 140) in a stepped pattern in the first reverse horizontal direction (the −X direction). The first reverse horizontal direction (the −X direction) may be a direction that is parallel with the surface of the upper semiconductor dies (130 and 140) and a second step direction in which the upper semiconductor dies (130 and 140) are stacked.

The first lower semiconductor die 110 may include the first lower body 112, the first lower die pad 114, which is arranged in an outer portion of the top surface of the first lower body 112 and exposed by the top surface of the first lower body 112, and the first adhesive layer 116 between the backside protective film 700 and the first lower body 112. The second lower semiconductor die 120 may include the second lower body 122, the second lower die pad 124, which is arranged in an outer portion of the top surface of the second lower body 122 and exposed by the top surface of the second lower body 122, and the second adhesive layer 126 between the first lower body 112 and the second lower body 122. The first upper semiconductor die 130 may include the first upper body 132, the first upper die pad 134, which is arranged in an outer portion of the top surface of the first upper body 132 and exposed by the top surface of the first upper body 132, and the third adhesive layer 136 between the second lower body 122 and the first upper body 132. The second upper semiconductor die 140 may include the second upper body 142, the second upper die pad 144, which is arranged in an outer portion of the top surface of the second upper body 142 and exposed by the top surface of the second upper body 142, and the fourth adhesive layer 146 between the first upper body 132 and the second upper body 142.

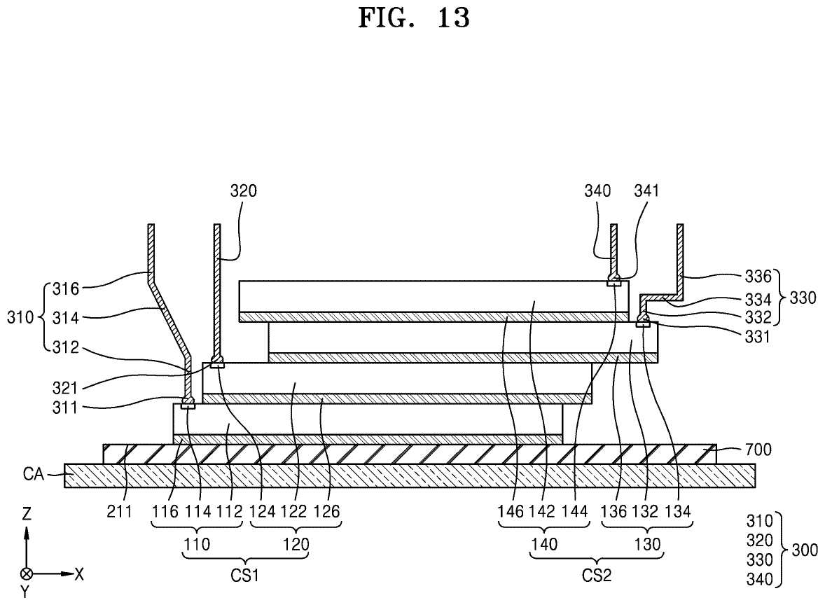

Referring to FIG. 13, the first bonding portion 310 and the second bonding portion 320 may be formed to be connected to the lower semiconductor die stack CS1, and the third bonding portion 330 and the fourth bonding portion 340 may be formed to be connected to the upper semiconductor die stack CS2. The first bonding portion 310 may be bonded to the first lower die pad 114 of the first lower semiconductor die 110. The second bonding portion 320 may be bonded to the second lower die pad 124 of the second lower semiconductor die 120. The third bonding portion 330 may be bonded to the first upper die pad 134 of the first upper semiconductor die 130. The fourth bonding portion 340 may be bonded to the second upper die pad 144 of the second upper semiconductor die 140.

The first bonding portion 310 may include the first upward wire 312 bonded to the first lower die pad 114, the inclined wire 314 connected to the first upward wire 312, and the second upward wire 316, which is connected the inclined wire 314 and extends in the vertical direction (the Z direction). In the process of bonding the first bonding portion 310 to the first lower semiconductor die 110, the first bonding portion 310 may be pressed against the first lower die pad 114. At this time, the end portion of the first upward wire 312 may be formed into the first bulge 311 due to physical and thermal pressure.

The second bonding portion 320 may be bonded to the second lower die pad 124 and may extend in the vertical direction (the Z direction). In the process of bonding the second bonding portion 320 to the second lower semiconductor die 120, the second bonding portion 320 may be pressed against the second lower die pad 124. At this time, the end portion of the second bonding portion 320 may be formed into the second bulge 321 due to physical and thermal pressure.

The third bonding portion 330 may include the third upward wire 332 bonded to the first upper die pad 134, the horizontal wire 334 connected to the third upward wire 332, and the fourth upward wire 336, which is connected the horizontal wire 334 and extends in the vertical direction (the Z direction). In the process of bonding the third bonding portion 330 to the first upper semiconductor die 130, the third bonding portion 330 may be pressed against the first upper die pad 134. At this time, the end portion of the third upward wire 332 may be formed into the third bulge 331 due to physical and thermal pressure.

The fourth bonding portion 340 may be bonded to the second upper die pad 144 and may extend in the vertical direction (the Z direction). In the process of bonding the fourth bonding portion 340 to the second upper semiconductor die 140, the fourth bonding portion 340 may be pressed against the second upper die pad 144. At this time, the end portion of the fourth bonding portion 340 may be formed into the fourth bulge 341 due to physical and thermal pressure.

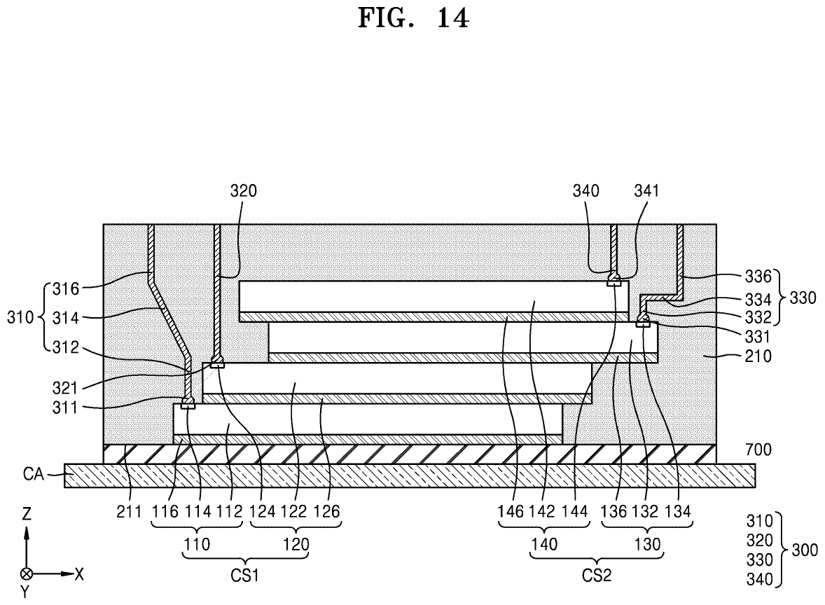

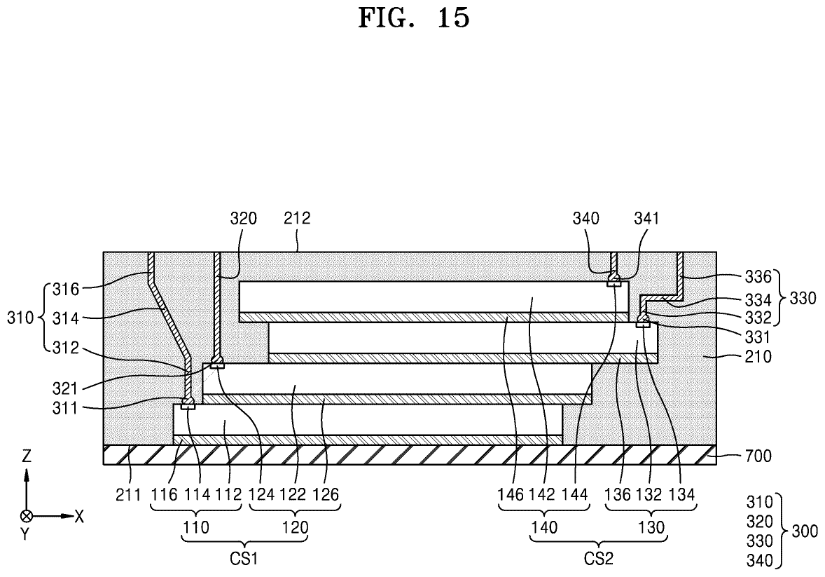

Referring to FIGS. 14 and 15, an encapsulation layer 210 may be formed by applying a molding material to the carrier substrate CA to mold the lower semiconductor die stack CS1, the upper semiconductor die stack CS2, and the first to fourth bonding portions 310, 320, 330, and 340.

Thereafter, the second upward wire 316, the second bonding portion 320, the fourth upward wire 336, the fourth bonding portion 340, and an upper portion of the encapsulation layer 210 may be partially polished. After the polishing, the carrier substrate CA may be removed. However, according to manufacturing processes, the carrier substrate CA may not be removed, and a subsequent process may be carried out with the carrier substrate CA attached to the bottom of the encapsulation layer 210,

After the upper portion of the encapsulation layer 210 is etched, the second upward wire 316, the second bonding portion 320, the fourth upward wire 336, and the fourth bonding portion 340 may be exposed by the second surface 212 of the encapsulation layer 210.

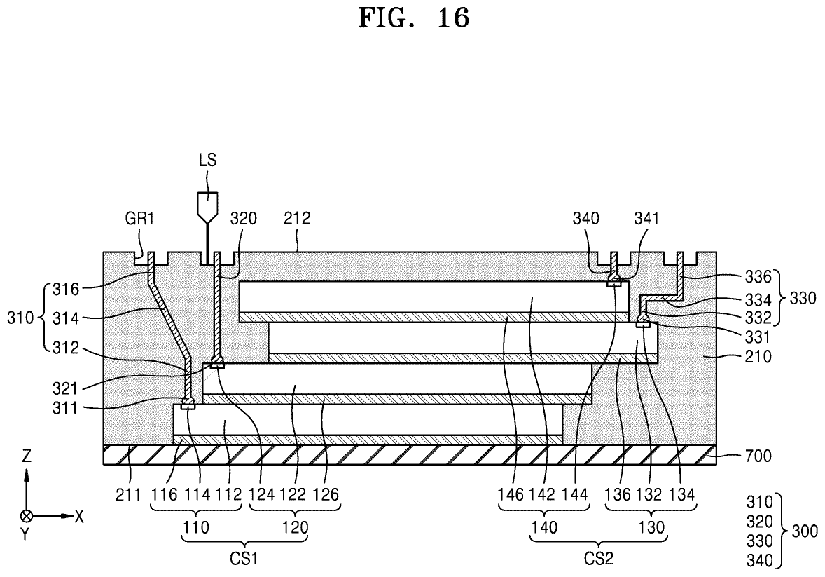

Referring to FIG. 16, a portion of the second surface 212 of the encapsulation layer 210 may be etched. The process of etching the encapsulation layer 210 may be performed using a laser device LS. The laser device LS may etch a portion of the second surface 212 of the encapsulation layer 210 by melting the portion of the encapsulation layer 210 by using a high-temperature laser. By etching the encapsulation layer 210, a plurality of grooves GR1 may be formed in the second surface 212 of the encapsulation layer 210. The laser device LS may form the grooves GR1 by radiating a laser to regions of the encapsulation layer 210, which respectively overlap the second upward wire 316, the second bonding portion 320, the fourth upward wire 336, and the fourth bonding portion 340.

At this time, the melting point of the encapsulation layer 210 may be lower than the melting point of the bonding wire group 300. The laser device LS may apply thermal energy to the encapsulation layer 210 to the extent that the encapsulation layer 210 melts but the bonding wire group 300 does not melt. Accordingly, the encapsulation layer 210 may partially melt, thereby forming the grooves GR1. However, the bonding wire group 300 does not melt so that the second upward wire 316, the second bonding portion 320, the fourth upward wire 336, and the fourth bonding portion 340 may be respectively exposed by the grooves GR1.

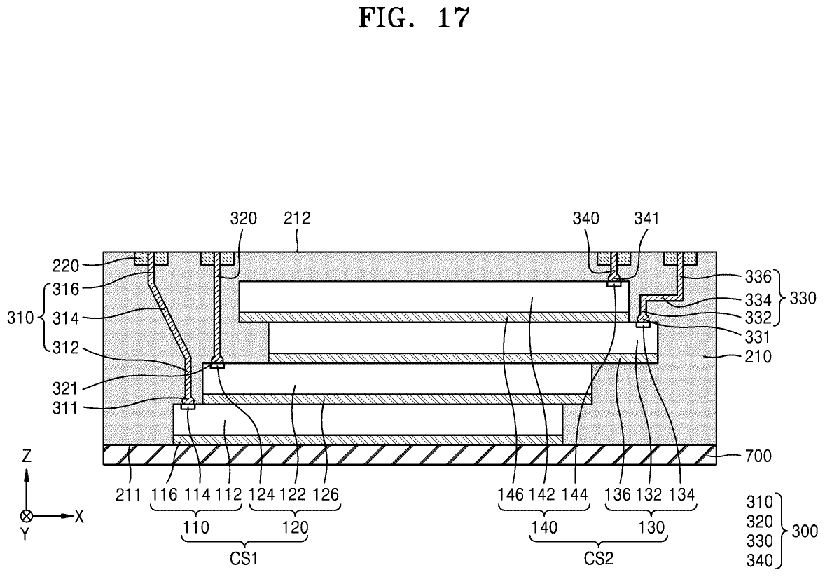

Referring to FIG. 17, the conductive connector 220 may be formed by filling each of the grooves GR1 in the second surface 212 of the encapsulation layer 210 with a conductive material. The conductive material may fill each groove GR1 such that there is no space within the groove GR1. For example, the conductive connector 220 may be formed using a blade printing method. However, a method of forming the conductive connector 220 is not limited thereto, and various methods may be used. The topmost surface of the conductive connector 220 may be coplanar with the second surface 212 of the encapsulation layer 210.

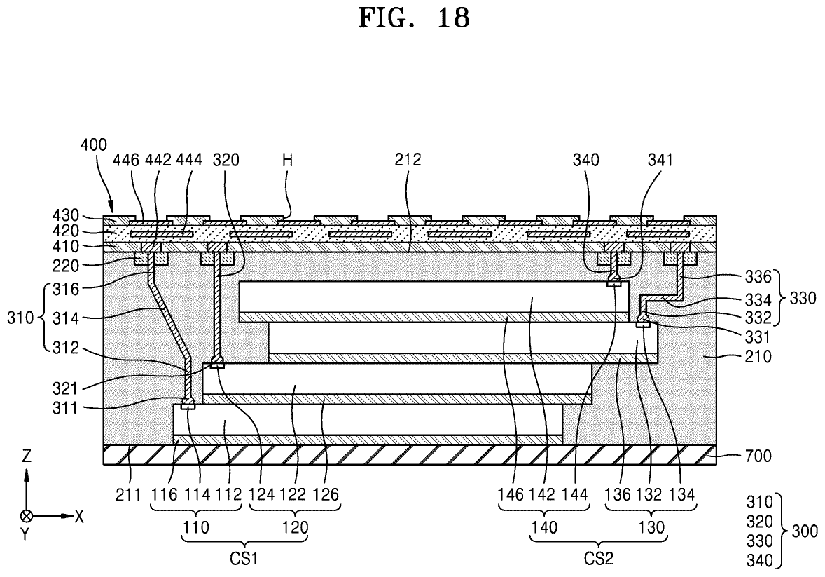

Referring to FIG. 18, the PCB 400 may be attached to the second surface 212 of the encapsulation layer 210. When the PCB 400 is attached to the second surface 212 of the encapsulation layer 210, a conductive pad 442 of the PCB 400 may be aligned with the conductive connector 220. Each of a plurality of conductive pads 442 exposed in the first photosensitive resist layer 410 of the PCB 400 may be attached to the conductive connector 220 exposed by the second surface 212 of the encapsulation layer 210. The width of the conductive connector 220 in the lateral direction (the X direction and/or the Y direction) may be greater than the width of each conductive pad 442 in the lateral direction (the X direction and/or the Y direction), and accordingly, the conductive pad 442 may be easily attached to the conductive connector 220.

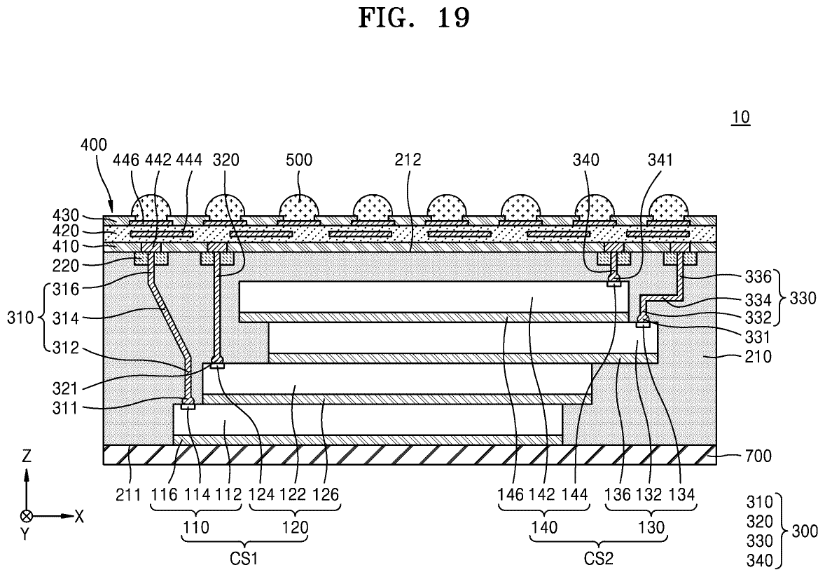

Referring to FIG. 19, an external connection terminal 500 may be attached to an external connection pad 446 exposed in the second photosensitive resist layer 430 of the PCB 400. For example, the external connection terminal 500 may include a solder ball or a bump. When the external connection terminal 500 is attached to the PCB 400, the semiconductor package 10 may be completely manufactured.

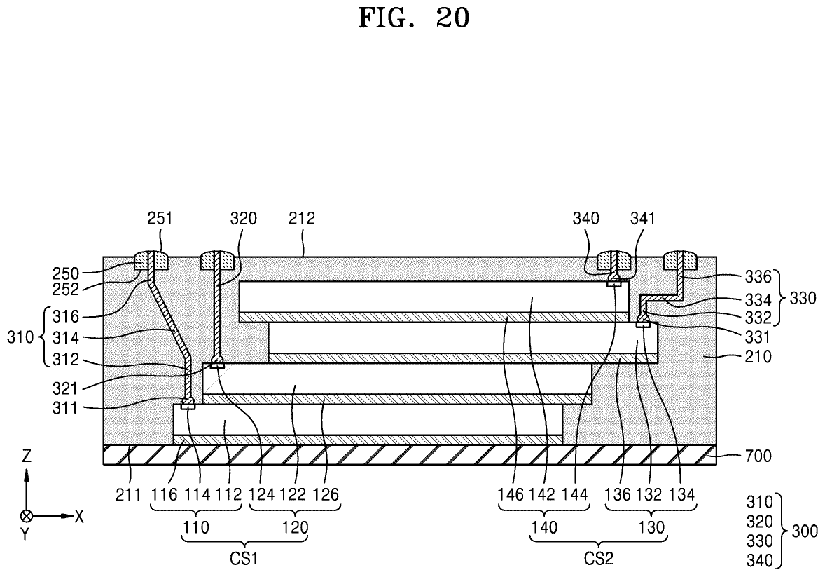

FIGS. 20 to 22 are cross-sectional views of operations in a method of manufacturing the semiconductor package 20, according to some embodiments.

FIG. 20 corresponds to FIG. 17. Accordingly, the descriptions given above with reference to FIGS. 12 to 16 are omitted below. A groove GR1 formed in the second surface 212 of the encapsulation layer 210 may be filled with a conductive material. The conductive material may fill the groove GR1 such that there is not space within the groove GR1. After the groove GR1 is filled with the conductive material, a reflow process may be carried out. During the reflow process, heat may be applied to the conductive material, and the central portion of the conductive material may protrude in the vertical direction (the Z direction) due to thermal expansion. When the conductive material thermally expands and protrudes, the conductive connector 250 may be completely formed. The vertical level of the conductive connector 250 in the vertical direction (the Z direction) may increase toward the center of the conductive connector 250.

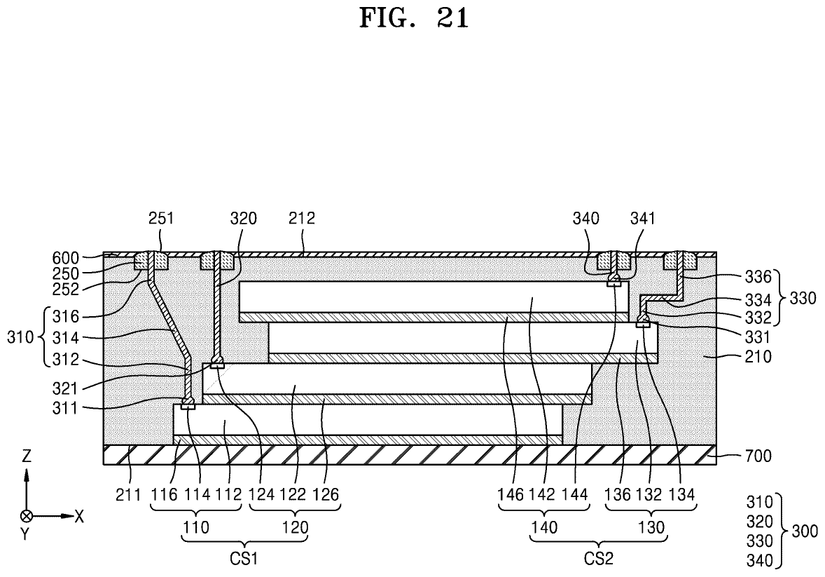

Referring to FIG. 21, the non-conductive film 600 may be attached to the second surface 212 of the encapsulation layer 210. In the process of attaching the non-conductive film 600 to the second surface 212 of the encapsulation layer 210, a portion of the non-conductive film 600 may be torn or turned into a hole by a protrusion of the conductive connector 250. A top end of the conductive connector 250 may be exposed by the torn portion or the hole of the non-conductive film 600. Accordingly, the topmost portion of the conductive connector 250 may not be in contact with the non-conductive film 600.

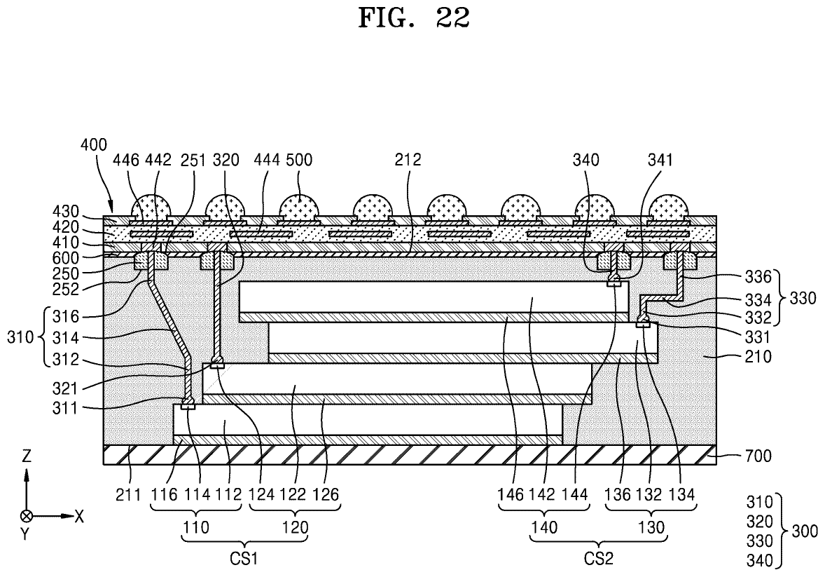

Referring to FIG. 22, the PCB 400 may be attached to the second surface 212 of the encapsulation layer 210. When the PCB 400 is attached to the second surface 212 of the encapsulation layer 210, a conductive pad 442 of the PCB 400 may be aligned with the conductive connector 250. Each of a plurality of conductive pads 442 exposed in the first photosensitive resist layer 410 of the PCB 400 may be attached to the conductive connector 250 exposed by the second surface 212 of the encapsulation layer 210. The width of the conductive connector 250 in the lateral direction (the X direction and/or the Y direction) may be greater than the width of each conductive pad 442 in the lateral direction (the X direction and/or the Y direction), and accordingly, the conductive pad 442 may be easily attached to the conductive connector 250. The portion of the bottom surface of the first photosensitive resist layer 410, which is not in contact with the conductive connector 250, may be in contact with the non-conductive film 600. Thereafter, a side portion of the encapsulation layer 210 may be cut through a blade process, and an identification number or character of the semiconductor package 20 may be engraved on the backside protective film 700 through a marking process.

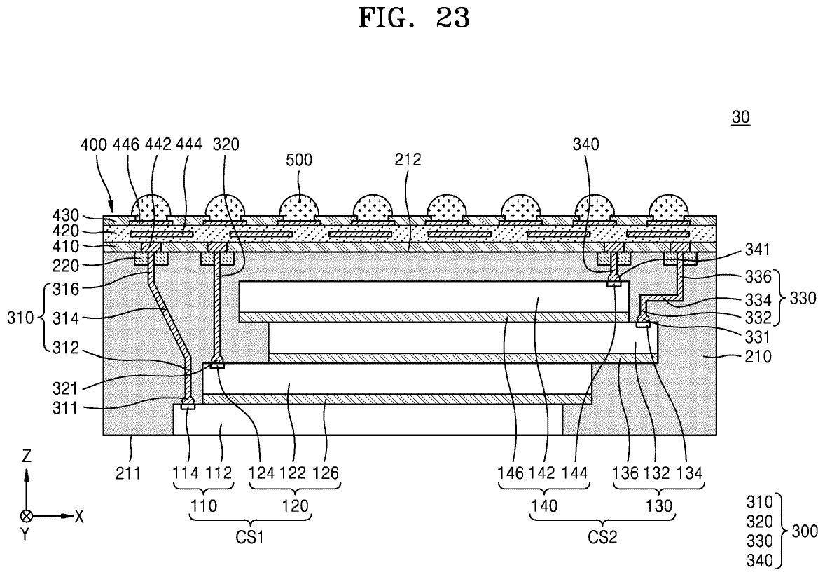

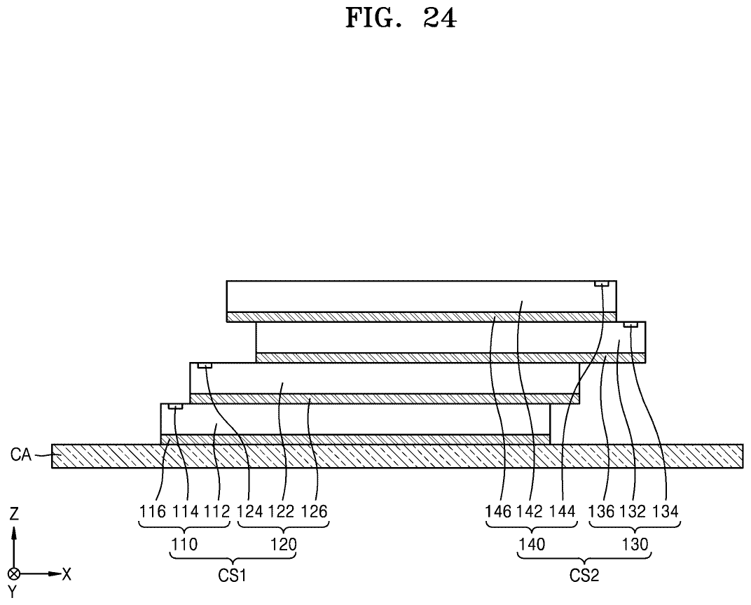

FIG. 23 is a cross-sectional view of a semiconductor package 30 according to an embodiment. FIG. 24 is a cross-sectional view of an operation in a method of manufacturing the semiconductor package 30 of FIG. 23.

The semiconductor package 30 of FIG. 23 is the same as or substantially the same as or similar to the semiconductor package 10 of FIG. 1, except that the semiconductor package 30 does not include the backside protective film 700. Accordingly, redundant descriptions of the elements described with reference to FIG. 1 are omitted below.

Referring to FIGS. 23 and 24, the first adhesive layer 116 may be directly attached to the carrier substrate CA, without the backside protective film 700. A plurality of lower semiconductor dies (110 and 120) and a plurality of upper semiconductor dies (130 and 140) may be stacked on the carrier substrate CA. Accordingly, in the case of the semiconductor package 30 of FIG. 23, the bottom surface of the first lower body 112 of the first lower semiconductor die 110 may be exposed, without the backside protective film 700.

While inventive concepts have been particularly shown and described with reference to embodiments thereof, it will be understood that various changes in form and details may be made therein without departing from the spirit and scope of the following claims.

What is claimed is:

1. A semiconductor package comprising:
a semiconductor die stack in a stepped pattern;
an encapsulation layer sealing the semiconductor die stack and including a first surface and a second surface, the first surface being coplanar with a bottommost surface of the semiconductor die stack and the second surface being opposite the first surface, the second surface having a groove;
a printed circuit board on the second surface of the encapsulation layer and including a conductive pad facing the second surface of the encapsulation layer;
a conductive connector filling the groove; and
a bonding wire group penetrating the conductive connector in a vertical direction and connecting the semiconductor die stack to the conductive pad of the printed circuit board,
wherein a width of the conductive connector in a lateral direction is greater than or equal to a width of the conductive pad in the lateral direction.

2. The semiconductor package of claim 1, wherein a length of the conductive connector in the vertical direction is greater than a length of the conductive pad in the vertical direction.

3. The semiconductor package of claim 1, wherein
the printed circuit board further includes a photosensitive resist layer in contact with the second surface of the encapsulation layer, and
the photosensitive resist layer is in contact with a portion of the conductive connector.

4. The semiconductor package of claim 1, wherein a melting point of the conductive connector is lower than a melting point of the bonding wire group.

5. The semiconductor package of claim 1, wherein
the bonding wire group includes a first bonding portion,
the first bonding portion includes a first upward wire connected to at least one semiconductor die of the semiconductor die stack, an inclined wire connected to the first upward wire, and a second upward wire extending toward the conductive connector and connecting the inclined wire to the conductive connector.

6. The semiconductor package of claim 1, wherein
the bonding wire group includes a second bonding portion, and
the second bonding portion extends in a straight line toward the conductive connector and connects at least one semiconductor die of the semiconductor die stack to the conductive connector.

7. The semiconductor package of claim 1, wherein
the bonding wire group includes a third bonding portion, and
the third bonding portion includes a third upward wire connected to at least one semiconductor die of the semiconductor die stack, a horizontal wire connected to the third upward wire, and a fourth upward wire extending to the conductive connector and connecting the horizontal wire to the conductive connector.

8. The semiconductor package of claim 1, wherein a topmost surface of the semiconductor die stack is apart from the second surface of the encapsulation layer in the vertical direction.

9. The semiconductor package of claim 1, wherein the conductive pad overlaps the conductive connector in the vertical direction and is in contact with the conductive connector.

10. The semiconductor package of claim 1, wherein
the conductive connector includes a top surface in contact with the printed circuit board, a bottom surface opposite the top surface, and an inclined surface extending from the top surface to the bottom surface,
the bottom surface of the conductive connector is in contact with the encapsulation layer, and
the bottom surface of the conductive connector has a smaller area than the top surface of the conductive connector.

11. A semiconductor package comprising:
a lower semiconductor die stack including a plurality of lower semiconductor dies stacked in a stepped pattern in a first horizontal direction;
an upper semiconductor die stack on the lower semiconductor die stack, the upper semiconductor die stack including a plurality of upper semiconductor dies stacked on the lower semiconductor die stack in a stepped pattern in a first reverse horizontal direction opposite to the first horizontal direction;
an encapsulation layer sealing the upper semiconductor die stack and the lower semiconductor die stack, the encapsulation layer including a first surface and a second surface, the first surface being coplanar with a bottommost surface of the lower semiconductor die stack and the second surface being opposite the first surface, the second surface having a plurality of grooves;
a printed circuit board on the second surface of the encapsulation layer and including a plurality of conductive pads facing the second surface of the encapsulation layer;
a first conductive connector, a second conductive connector, and a third conductive connector respectively filling the plurality of grooves;
a first bonding wire group penetrating the first conductive connector in a vertical direction and connecting the lower semiconductor die stack to some of the plurality of conductive pads of the printed circuit board; and
a second bonding wire group penetrating the second conductive connector and the third conductive connector in the vertical direction and connecting the upper semiconductor die stack to other conductive pads among the conductive pads of the printed circuit board,
wherein a width of the first conductive connector, a width of the second conductive connector, and a width the third conductive connector in a lateral direction are greater than or equal to widths of each of the plurality of conductive pads in the lateral direction.

12. The semiconductor package of claim 11, wherein
the lower semiconductor die stack includes a first lower semiconductor die at a bottom of the lower semiconductor die stack and a second lower semiconductor die on the first lower semiconductor die in the stepped pattern of the lower semiconductor die stack,
the first bonding wire group includes a first bonding portion connecting the first lower semiconductor die to one of the plurality of conductive pads and a second bonding portion connecting the second lower semiconductor die to an other one of the plurality of conductive pads, and
the first bonding portion and the second bonding portion penetrate the first conductive connector and are electrically connected to each other via the first conductive connector.

13. The semiconductor package of claim 11, wherein
the upper semiconductor die stack includes a first upper semiconductor die in contact with the lower semiconductor die stack and a second upper semiconductor die stacked on the first upper semiconductor die in the stepped pattern of the upper semiconductor die stack,
the second bonding wire group includes a third bonding portion connecting the first upper semiconductor die to one of the plurality of conductive pads and a fourth bonding portion connecting the second upper semiconductor die to an other one of the plurality of conductive pads,
the third bonding portion penetrates the second conductive connector,
the fourth bonding portion penetrates the third conductive connector, and
the third bonding portion is not electrically connected to the fourth bonding portion.

14. The semiconductor package of claim 11, wherein
the first conductive connector, the second conductive connector, and the third conductive connector each protrude in the vertical direction, and
a vertical level of a topmost end of each of the first conductive connector, the second conductive connector, and the third conductive connector is higher than a vertical level of the second surface of the encapsulation layer.

15. The semiconductor package of claim 14, wherein vertical levels of each of the first conductive connector, the second conductive connector, and the third conductive connector increases toward a center of each of the first conductive connector, the second conductive connector, and the third conductive connector.

16. The semiconductor package of claim 11, further comprising
a non-conductive film covering the second surface of the encapsulation layer,
wherein each of the first conductive connector, the second conductive connector, and the third conductive connector protrude through the non-conductive film in the vertical direction.

17. The semiconductor package of claim 16, wherein the printed circuit board further includes a photosensitive resist layer in contact with the non-conductive film lengthwise.

18. The semiconductor package of claim 11, wherein
each of the first conductive connector, the second conductive connector, and the third conductive connector includes at least one selected from the group consisting of tin (Sn), indium (In), bismuth (Bi), antimony (Sb), copper (Cu), silver (Ag), zinc (Zn), lead (Pb), and an alloy thereof.

19. A semiconductor package comprising:
a lower semiconductor die stack including a plurality of lower semiconductor dies stacked in a stepped pattern in a first horizontal direction, the first horizontal direction being parallel with surfaces of the plurality of lower semiconductor dies and corresponding to a first step direction in which the plurality of lower semiconductor dies are stacked;
an upper semiconductor die stack including a plurality of upper semiconductor dies stacked on the lower semiconductor die stack in a stepped pattern in a first reverse horizontal direction, the first reverse horizontal direction being opposite the first horizontal direction and parallel with surfaces of the plurality of upper semiconductor dies and corresponding to a second step direction in which the plurality of upper semiconductor dies are stacked, the second step direction being opposite the first step direction of the plurality of lower semiconductor dies;
an encapsulation layer sealing the upper semiconductor die stack and the lower semiconductor die stack, the encapsulation layer including a first surface and a second surface, the first surface being coplanar with a bottommost surface of the lower semiconductor die stack and the second surface being opposite the first surface, the second surface having a plurality of grooves;
a printed circuit board including a solder ball attached to a first photosensitive resist layer, an insulating layer, and a second photosensitive resist layer, the first photosensitive resist layer including a plurality of conductive pads facing the second surface of the encapsulation layer, and the first photosensitive resist layer, the insulating layer, and the second photosensitive resist layer being sequentially stacked on the second surface of the encapsulation layer;
a first conductive connector, a second conductive connector, and a third conductive connector respectively filling the plurality of grooves;
a first bonding wire group penetrating the first conductive connector in a vertical direction and connecting the lower semiconductor die stack to some of the plurality of conductive pads of the printed circuit board; and
a second bonding wire group penetrating the second conductive connector and the third conductive connector in the vertical direction and connecting the upper semiconductor die stack to other conductive pads among the conductive pads of the printed circuit board,
wherein a width of the first conductive connector, a width of the second conductive connector, and a width of the third conductive connector in a lateral direction are greater than or equal to widths of each of the plurality of conductive pads in the lateral direction.

20. The semiconductor package of claim 19, wherein
the lower semiconductor die stack includes a first lower semiconductor die at a bottom of the lower semiconductor die stack and a second lower semiconductor die on the first lower semiconductor die in the stepped pattern of the lower semiconductor die stack,
the first bonding wire group includes a first bonding portion connecting the first lower semiconductor die to one of the plurality of conductive pads and a second bonding portion connecting the second lower semiconductor die to an other one of the plurality of conductive pads,
the first bonding portion and the second bonding portion penetrate the first conductive connector and are electrically connected to each other via the first conductive connector,
the upper semiconductor die stack includes a first upper semiconductor die in contact with the lower semiconductor die stack and a second upper semiconductor die on the first upper semiconductor die in the stepped pattern of the upper semiconductor die stack,
the second bonding wire group includes a third bonding portion connecting the first upper semiconductor die to one of the plurality of conductive pads and a fourth bonding portion connecting the second upper semiconductor die to an other one of the plurality of conductive pads,
the third bonding portion penetrates the second conductive connector, the fourth bonding portion penetrates the third conductive connector, and
the third bonding portion is not electrically connected to the fourth bonding portion.
